(19) United States
(12) Patent Application Publication
(10) Pub. No.: US 2025/0391663 A1
(43) Pub. Date: Dec. 25, 2025

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Shin-Li Wang, Pingtung County (TW); Kai Ju Lin, Taipei City (TW); Zu-Yin Liu, Taipei City (TW); Chi-Chen Wu, Hsinchu City (TW); Szu-Ping Lee, Changhua County (TW); You-Ting Lin, Miaoli County (TW); Jiun-Ming Kuo, Taipei City (TW); Yuan-Ching Peng, Hsinchu (TW); Chen-Ping Chen, Yilan County (TW)

(21) Appl. No.: 18/941,682

(22) Filed: Nov. 8, 2024

Related U.S. Application Data
(60) Provisional application No. 63/662,560, filed on Jun. 21, 2024.

(51) Int. Cl. H01L 21/3065; H01L 21/8234; H01L 27/088; H01L 29/06; H01L 29/10; H01L 29/423; H01L 29/66; H01L 29/775; H01L 29/786

(52) U.S. Cl. CPC H01L 21/3065; H10D 62/364; H10D 84/0128; H10D 84/038; H10D 84/83; H10D 30/014; H10D 30/43; H10D 30/6735; H10D 30/6757; H10D 62/121

(57) ABSTRACT

A method includes forming a first fin protruding from a substrate at a center region, and a second fin protruding from the substrate at an edge region, the first fin and second fin each including an epitaxial stack over a fin base and a hard mask layer over the epitaxial stack. A patterning material is deposited adjacent to and over each of the first fin and the second fin. Different etch process parameters are used to etch the first fin at the center region than the etch process parameters of the second fin at the edge region.

### PRIORITY DATA

This application claims priority to U.S. Provisional Patent Application No. 63/662,560 filed on Jun. 21, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

To enhance the device controllability and reduce the substrate surface area occupied by the planar devices, the semiconductor industry has progressed into nanometer technology process nodes in pursuit of higher device density, higher performance, and lower costs. Challenges from both fabrication and design issues have resulted in the development of three-dimensional designs, such as a multi-gate field effect transistor (FET), including a fin field effect transistor (FinFET) and a gate-all-around (GAA) field effect transistor (FET). In a FinFET, a gate electrode is adjacent to three side surfaces of a channel region with a gate dielectric layer interposed therebetween. Because the gate structure surrounds the fin on three surfaces (i.e., the top surface and the opposite lateral surfaces), the transistor essentially has three gates controlling (one gate at each of the top surface and the opposite lateral surfaces) the current through the fin or channel region. In a GAA FET, all side surfaces (i.e. the top surface, the opposite lateral surfaces, and the bottom surface) of the channel region are surrounded by the gate electrode, which allows for fuller depletion in the channel region and results in reduced short-channel effect due to steeper sub-threshold current swing (SS) and smaller drain induced barrier lowering (DML). As dimensions are continually scaled down to sub-micron technology nodes, further improvements of device configurations and fabrication thereof are desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a semiconductor substrate, a wafer, in accordance with some embodiments of the present disclosure.

FIG. 2 illustrates a flowchart of an example method for fabricating a semiconductor device, in accordance with some embodiments of the present disclosure.

FIGS. 3A, 4A, 5A, 6A, 7A, 8A, 9A, 10A, 11A, 12A, 13A, 14A, 15A, 16A, 17A, and 18A illustrate perspective views of a semiconductor device constructed according to the method in FIG. 2, in accordance with some embodiments.

FIGS. 3B, 4B, 5B, 6B, 7B, 8B, 9B, 10B, 11B, 12B, 13B, 14B, 15B, 16B, 17B, and 18B illustrate cross-sectional views in an X-Z plane of a portion of the semiconductor device in respective perspective views during fabrication processes according to the method of FIG. 2, in accordance with some embodiments of the present disclosure.

FIGS. 3C, 4C, 5C, 6C, 7C, 8C, 9C, 10C, 11C, 12C, 13C, 14C, 15C, 16C, 17C, and 18C illustrate cross-sectional views in a Y-Z plane of a portion of the semiconductor device in respective perspective views during fabrication processes according to the method of FIG. 2, in accordance with some embodiments of the present disclosure.

FIG. 19 illustrates a graphical illustration of a sidewall configuration at an edge region and a center region of an exemplary device, in accordance with some embodiments of the present disclosure.

FIGS. 20-22 illustrate cross-sectional views regarding a region of the semiconductor device during fabrication processes according to the method of FIG. 2, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Some processes of manufacturing semiconductor devices, such as, fin field effect transistors (FinFETs) and/or gate-all-around (GAA) field effect transistors (FETs) may involve forming features which project from the substrate referred to as fins that provide the active region of the device, where the fins are defined and formed using lithography processes. After fins are formed, a number of fins or certain portions of selected fins are removed by a fin cut process. For example, a fin cut process may remove a portion of a fin and thus “cuts” the otherwise continuous fin (i.e., continuous active region) into two separated fins (i.e., two separate active regions). Isolation features, such as shallow trench isolation (STI) features, are formed where the fin is cut and protect the fin edges formed by the fin cut process. This process is also employed in fabrication of devices such as complementary field effect transistors (CFETs) and/or other stacked transistors that also utilize active regions defined in fins. CFETs are a stacked device providing a n-type FET over a p-type FET (or vice versa) that can be formed using GAA transistor structures.

A cut process (an active region cut, herein referred to as a fin cut process) may produce a fin edge profile that is oblique to a horizontal direction in which the length of the fin extends. With the ever-decreasing device dimensions along the advancement of process nodes, the profile of this oblique configuration can affect quality and reliability of the device. In particular, due to across-substrate (across-wafer) variations introduced during fabrication, it is important to control the nature of the variation (e.g., profile variations of oblique fin edge) between areas of the wafer. In some embodiments, the present disclosure provides for a process flow that can result in minimization of fin edge profile variations across-wafer. In some embodiments, the extent and location of the bowing of the opening/fin edge that forms a bulb-like shape can be controlled to be substantially similar across-wafer. The bowing may refer to the extent of deviation from horizontal (e.g., curvilinear sidewall) in providing a cut fin edge.

The disclosed structure and the method of making the same are applicable to a semiconductor structure having FETs with a three-dimensional structure, such as fin FETs (FinFETs) formed on fin active regions, and FETs with vertically-stacked multiple channels, such as gate-all-around (GAA) structure. For the purposes of simplicity, the present disclosure uses GAA transistors as an example. Those of ordinary skill in the art should appreciate that they may readily use the present disclosure as a basis for designing or modifying other processes and structures (such as FinFETs) for carrying out the same purposes and/or achieving the same advantages of the embodiments introduced herein.

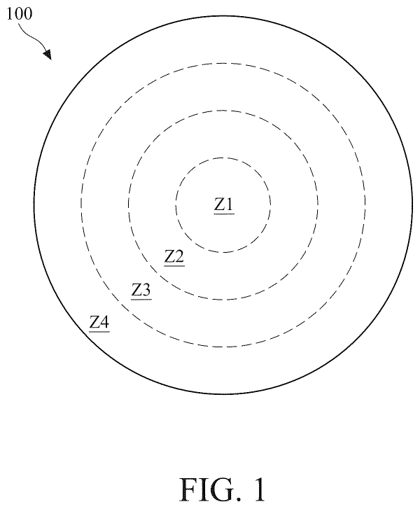

FIG. 1 illustrates a top view of a substrate 100, also referred to as a wafer 100. The fabrication of semiconductor devices such as the FETs discussed above, involves the transferring of patterns onto a surface of a semiconductor wafer, such as wafer 100. A semiconductor device is significantly smaller than the semiconductor wafer, with an array of devices formed on the wafer. The wafer is, after processing, separated into individual die, which themselves can include millions or more transistors. The wafer 100 may be of a suitable diameter such as 200 mm, 300 mm, 450 mm, and/or other typical wafer sizes.

The wafer 100 of FIG. 1 is designated into various zones for ease of illustration and explanation. The zones, Z1, Z2, Z3, and Z4 are exemplary only and any number of zones may be provided. In an embodiment, the edge zone ZA is the portion of the wafer having a radius greater than approximately 120 mm (e.g., in a 300 mm diameter embodiment of the wafer 100). In an embodiment, the zone ZA includes an outer 15% or less of the wafer 100. In an embodiment, the zone Z4 includes an outer 10% of the wafer 100. It is noted that an exclusion zone may be disposed outside of zone Z4 to the edge of the wafer 100 in which die or portions thereof may be formed but not used. The cross-sectional view provided along cross-section B-B′ is provided in the center zone Z1, but equally applies to the edge region Z4.

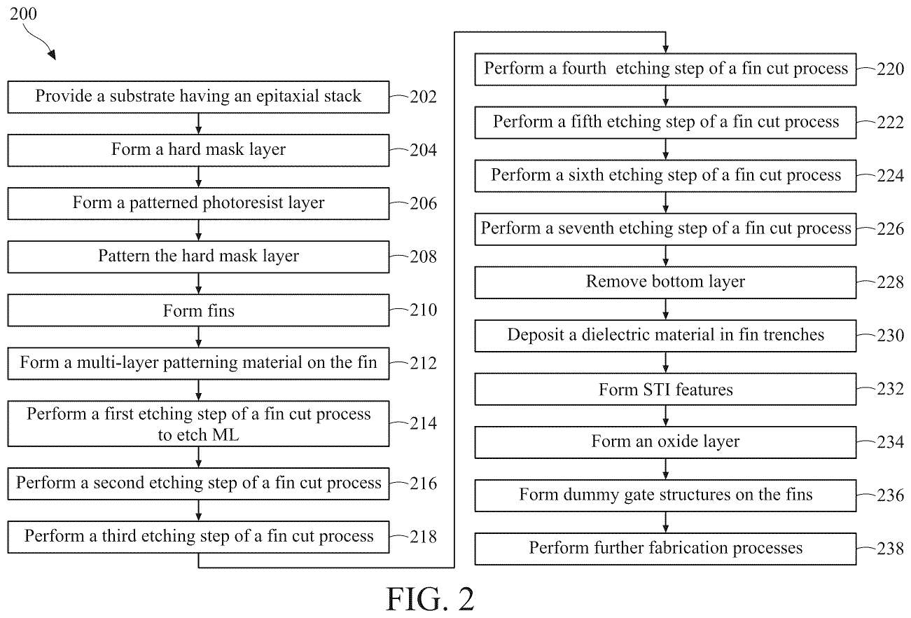

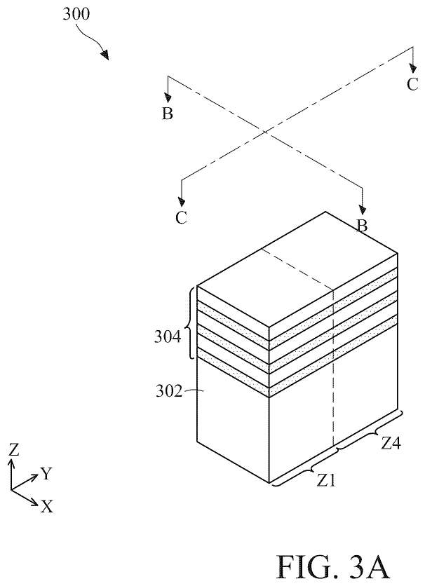

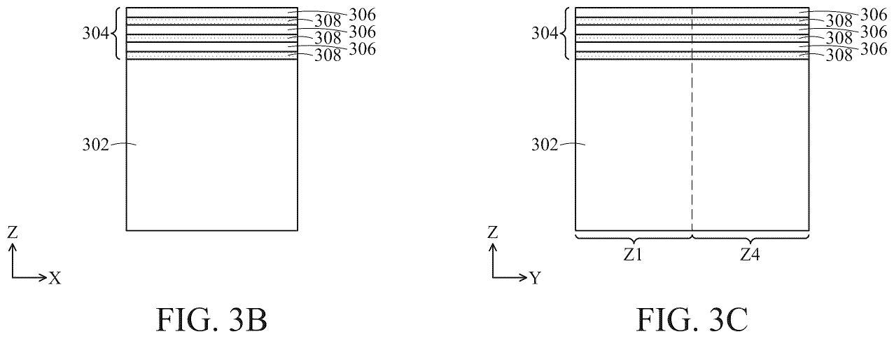

FIG. 2 illustrates a flow chart of a method 200 for fabricating a semiconductor device according to various embodiments of the present disclosure. The semiconductor device may be fabricated on a semiconductor substrate substantially similar to wafer 100 of FIG. 1. It is noted that the method 200 is exemplary and additional operations can be provided before, during, and after method 200, and some of the operations described can be moved, replaced, or eliminated for additional embodiments of method 200. FIG. 2 is described below in conjunction with figures labeled FIG. 3A through FIG. 18C that illustrate various perspective and cross-sectional views of a semiconductor structure 300 at various steps of fabrication according to the method 200, in accordance with some embodiments. The figures illustrate a first structure (or device) in a center region Z1 of the substrate 100 and a second structure (or device) in an edge region Z4 of the substrate 100. In an embodiment, the structure in the center region Z1 is provided on a first chip (or die) and the structure in the edge region Z4 is provided on a second chip (or die) after the wafer 100 is diced.

In some embodiments, the structure 300 includes an IC chip, a system on chip (SoC), or portion thereof, that includes various passive and active microelectronic devices such as resistors, capacitors, inductors, diodes, p-type field effect transistors (PFETs), n-type field effect transistors (NFETs), nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. As discussed above, the FETs may be multi-gate devices such as FinFETs, GAA, and/or CFET configurations. FIGS. 3A-18C have been simplified for the sake of clarity to better understand the inventive concepts of the present disclosure. Additional features can be added in the structure 300, and some of the features described below can be replaced, modified, or eliminated in other embodiments of the structure 300.

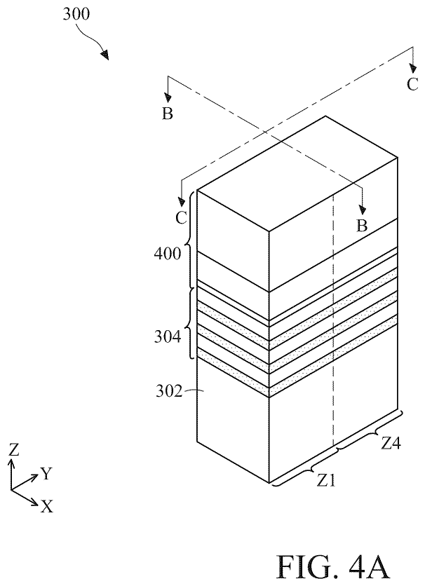

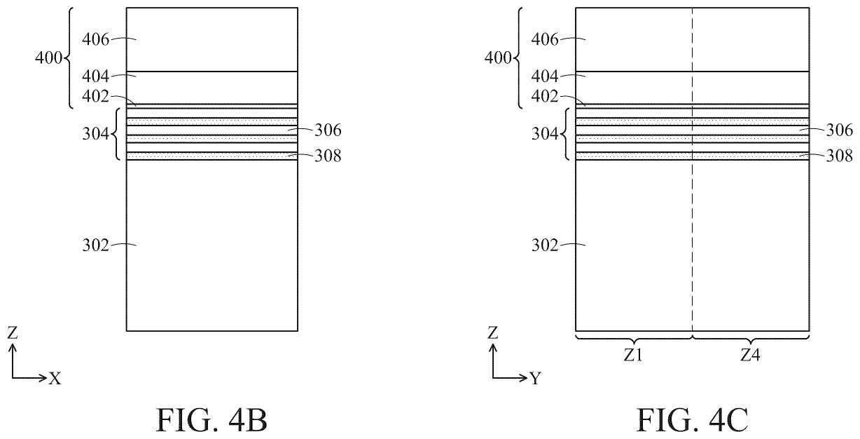

At block 202, the method 200 (FIG. 2) provides a substrate 302 and an epitaxial stack 304 disposed on the substrate 302, as shown in FIGS. 3A-3C. FIG. 3A illustrates a perspective view of the device 300, and FIGS. 3B and 3C illustrate cross-sectional views of the device 300, in portion, along the B-B line and the C-C line in FIG. 3A, respectively. Particularly, the B-B line is a cut along the lengthwise direction of to-be-formed semiconductor fins or active regions (direction “X” or X-direction) and the C-C line is a cut in a direction perpendicular to the lengthwise direction of to-be-formed semiconductor fins or active regions (direction “Y” or Y-direction). Thus, FIG. 3B is a cross-sectional view in an X-Z plane, and FIG. 3C is a cross-sectional view in a Y-Z plane. The B-B lines and C-C lines in FIGS. 4A through 18C are similarly configured.

In some embodiments, the substrate 302 is a silicon-on-insulator (SOI) substrate. Semiconductor-on-insulator substrates can be fabricated using separation by implantation of oxygen (SIMOX), wafer bonding, and/or other suitable methods. In an alternative embodiment, the substrate 302 is a bulk silicon substrate (i.e., including bulk single-crystalline silicon). The substrate 302 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GalnAs, GaInP, GaInAsP, or combinations thereof.

The epitaxial stack 304 includes epitaxial layers 306 of a first composition interposed by epitaxial layers 308 of a second composition. The first and second compositions can be different. In an embodiment, the epitaxial layers 308 are SiGe layers and the epitaxial layers 306 are Si layers. However, other embodiments are possible including those that provide for a first composition and a second composition having different oxidation rates and/or etch selectivity. As described further below, the epitaxial layers 306 or portions thereof form channel regions of the device 300. And the epitaxial layers 308 are sacrificial layers. In the depicted embodiment, the epitaxial stack 304 includes three epitaxial layers 306 and three epitaxial layers 308 configured to form three semiconductor layer pairs disposed over the substrate 302, each semiconductor layer pair having a respective first epitaxial layer 306 and a respective second epitaxial layer 308. After undergoing subsequent processing, such configuration will result in the device having three channel layers. However, the present disclosure contemplates embodiments where the epitaxial stack 304 includes more or less semiconductor layers, for example, depending on a number of channels desired for the device 300 (e.g., a GAA transistor, a CFET transistor) and/or design requirements of the device 300. For example, the epitaxial stack 304 can include two to ten epitaxial layers 306 and two to ten epitaxial layers 308. In an alternative embodiment where the structure formed is a FinFET device, the epitaxial stack 304 is simply one layer of a semiconductor material, such as one layer of Si extending above the substrate 302. In an embodiment, the epitaxial layers 304 are omitted and the fin (e.g., active region) is etched into the substrate 302.

By way of example, the epitaxial stack 304 may be epitaxially grown on the substrate 302. The epitaxial growth be performed by a molecular beam epitaxy (MBE) process, a metalorganic chemical vapor deposition (MOCVD) process, and/or other suitable epitaxial growth processes. In furtherance of the embodiments, either of the epitaxial layers 306 and 308 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 306 and 308 may be chosen based on providing differing oxidation and etch selectivity properties. In some embodiments, the epitaxial layers 308 have a first etch rate to an etchant and the epitaxial layers 306 have a second etch rate to the etchant, where the second etch rate is less than the first etch rate. In some embodiments, the epitaxial layers 308 have a first oxidation rate and the epitaxial layers 306 have a second oxidation rate, where the second oxidation rate is less than the first oxidation rate. The epitaxial layers 308 and the epitaxial layers 306 include different materials, constituent atomic percentages, constituent weight percentages, thicknesses, and/or characteristics to achieve desired etching selectivity during an etching process, such as an etching process implemented to form suspended channel layers in channel regions of the device 300. For example, where the epitaxial layers 308 include silicon germanium and the epitaxial layers 306 include silicon, a silicon etch rate of the epitaxial layers 306 is less than a silicon germanium etch rate of the epitaxial layers 308 for given etchant. In some embodiments, the epitaxial layers 306 and the epitaxial layers 308 can include the same material but with different constituent atomic percentages to achieve the etching selectivity and/or different oxidation rates. For example, the epitaxial layers 306 and the epitaxial layers 308 can include silicon germanium, where the epitaxial layers 306 have a first silicon atomic percent and/or a first germanium atomic percent and the epitaxial layers 308 have a second, different silicon atomic percent and/or a second, different germanium atomic percent. The present disclosure contemplates that the epitaxial layers 306 and the epitaxial layers 308 include any combination of semiconductor materials that can provide desired etching selectivity, desired oxidation rate differences, and/or desired performance characteristics (e.g., materials that maximize current flow), including any of the semiconductor materials disclosed herein.

In some embodiments, the epitaxial layer 306 has a thickness (e.g., in the z-direction) ranging from about 3 nm to about 6 nm. In furtherance of the embodiments, the epitaxial layers 306 in the epitaxial stack 304 may be substantially uniform in thickness. As described in more detail below, in the illustrated embodiment, the epitaxial layers 306 serve as channel layers for a GAA transistor and the thickness is chosen based on device performance considerations. The epitaxial layers 308 serve to reserve a spacing (or referred to as a gap) between adjacent channel structures for a GAA transistor and the thickness is chosen based on device performance considerations as well. Accordingly, the epitaxial layers 308 are also referred to the sacrificial layers 308 and the epitaxial layers 306 are also referred to as the channel layers 306 or the nanostructures 306. A nanostructure may include a nanowire configuration, nanosheet configuration and/or other configuration including as discussed below. It is noted that the uppermost layer in some embodiments may be epitaxial layer 306, however other implementations may be possible.

At operation 204, the method 200 forms a hard mask layer over the epitaxial stack of block 202 in order to pattern the epitaxial stack. In particular, as illustrated in FIGS. 4A-4C, a patterning layer 400 is provided including a pad oxide layer 402 over the epitaxial stack 304, a nitride layer 404 over the pad oxide layer 402, and an oxide layer 406 over the nitride layer 404, as shown in FIGS. 4A-4C. In some embodiments, the pad oxide layer 402 is made of silicon oxide, which can be formed by a thermal oxidation process; the nitride layer 404 is made of silicon nitride (SiN), which can be formed by chemical vapor deposition (CVD), including low pressure CVD (LPCVD) and plasma enhanced CVD (PECVD), physical vapor deposition (PVD), atomic layer deposition (ALD), or other suitable process; the oxide layer 406 may be formed by CVD, PVD, ALD, or other suitable process. Various other patterning materials may be formed additionally or alternatively to those shown. The hard mask layer 400 may also be referred to as an insulating layer as it is comprised of dielectric materials.

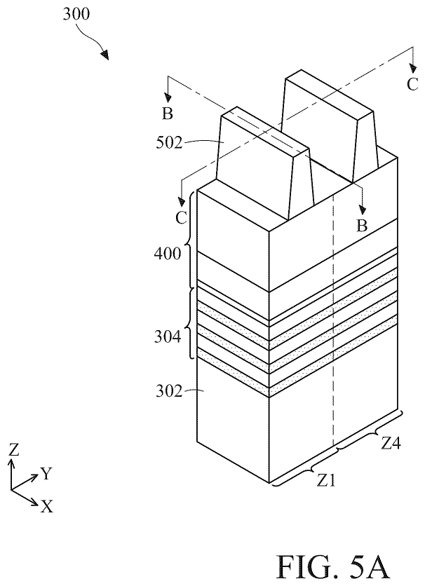

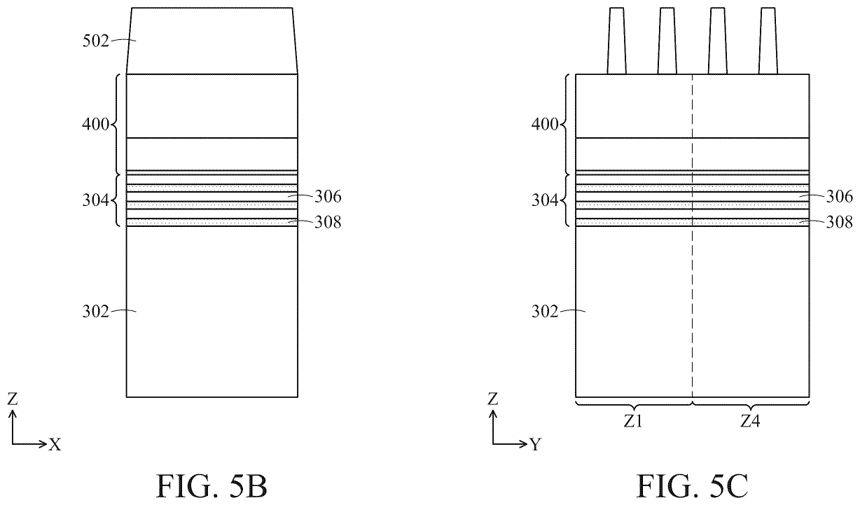

At block 206, the method 200 deposits a photosensitive layer that is patterned. In an example, a photoresist layer 502 over the hard mask layer 400, as shown in FIGS. 5A-5C. The photoresist layer 502 is patterned to define fins (e.g., active regions). The photoresist layer 502 is patterned using patterning techniques including, for example, electron-beam lithography, photolithography, or any other suitable process. Various other patterning processes may be implemented such as forming mandrels.

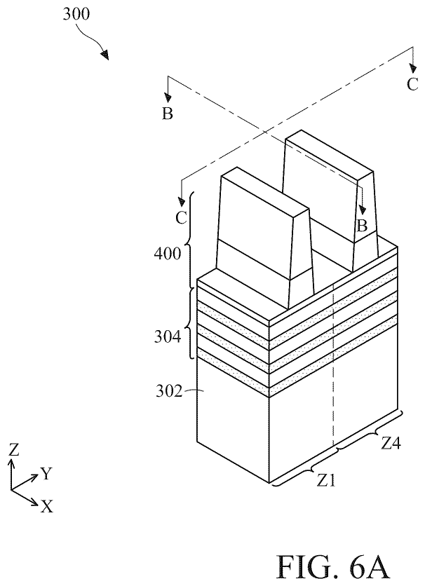

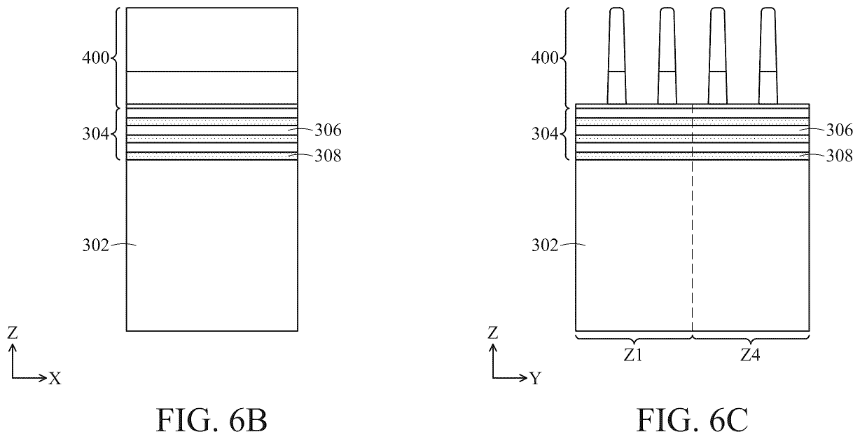

At block 208, the method 200 performs an etching operation on the hard mask layer using the patterned photoresist layer as an etch mask. FIGS. 6A-6C are illustrative. In an embodiment, the pad oxide layer 402 serves as an etch stop layer, protecting the top surface of the epitaxial layer 306 from being damaged by the etching operation. The photoresist layer 502 is removed by a suitable photoresist stripping or plasma ashing operation. For example, in some embodiments, a suitable solvent is used to remove the photoresist layer 502. In some other embodiments, the photoresist layer 502 is removed by oxygen plasma ashing operation.

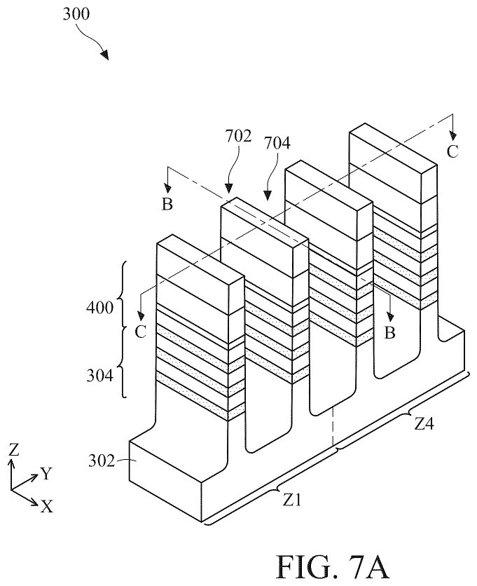

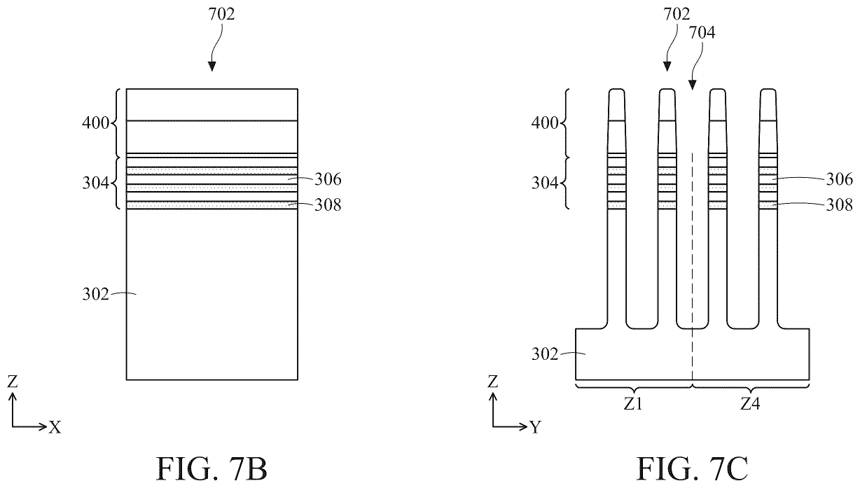

At block 210, the method 200 patterns the epitaxial stack to form semiconductor fins or active regions in a fin structure. Referring to the example of FIGS. 7A-7C, fin structures 702 and trenches 704 between adjacent fins 702 using the patterned hard mask layer 400 as an etch mask, as shown in FIGS. 7A-7C. In various embodiments, each of the fins 702 includes a top portion of the alternating epitaxial layers 306 and 308 and a bottom portion that is formed by patterning a top portion of the substrate 302. The bottom portion of a fin 702 is also referred to as a fin base or a mesa. In some embodiments, the patterning of the epitaxial stack 304 is performed using various methods including a wet etchant such as, but not limited to, ammonium hydroxide (NH₄OH), tetramethylammonium hydroxide (TMAH), ethylenediamine pyrocatechol (EDP), or potassium hydroxide (KOH) solutions. In other embodiments, the etching operation is performed using a wet etchant such as, but not limited to, HF:HNO₃ solution, HF:CH₃COOH:HNO₃, or H₂SO₄ solution and HF:H₂O₂: CH₃COOH. In some embodiments, a dry etching operation is used. The dry etching operation may use an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, a combination of dry etching techniques and wet etching techniques are used to perform the etching operations.

Still referring to FIGS. 7A-7C, each of the fins 702 protrudes upwardly in the Z-direction above the substrate 302 and extends lengthwise in the X-direction. The number of fins 702 are illustrative only and not limited to as illustrated. The fins 702 may have a uniform fin width along the Y-direction. As shown in further detail below, a fin cut process is performed to “cut” one of the fins 702 into two separated segments along the x-direction.

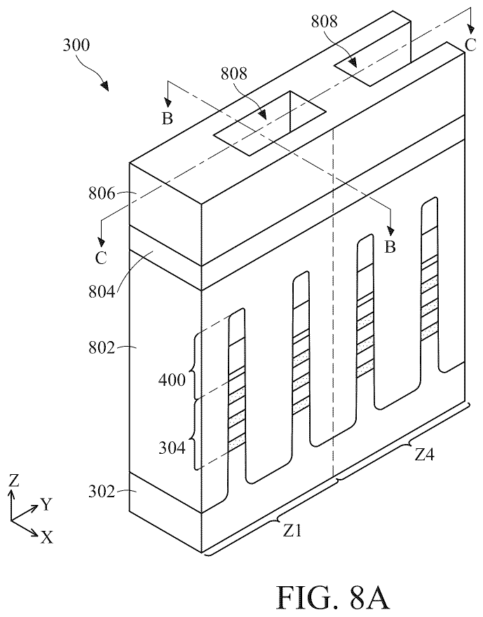

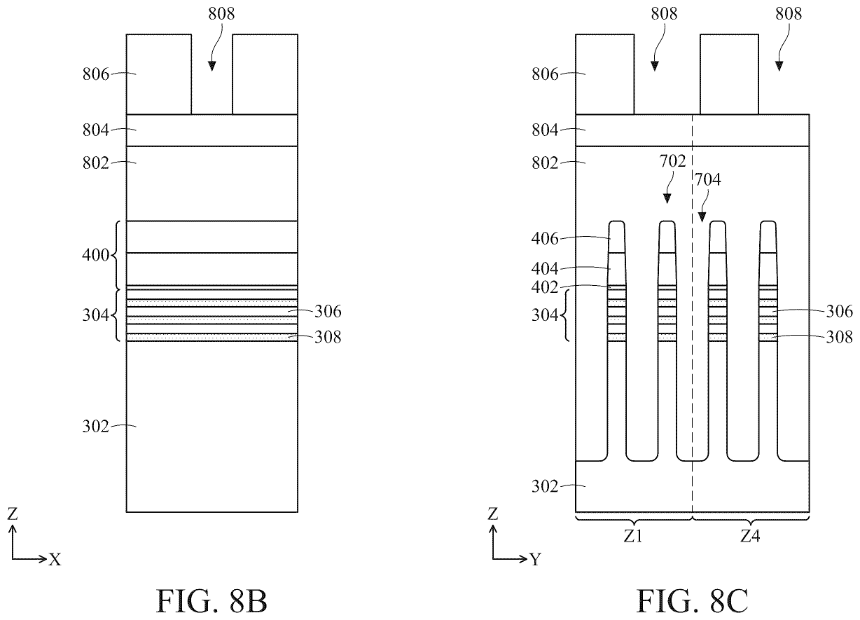

At block 212, the method 200 forms a multi-layer patterning layer is formed over the device including the fin structures. Referring to the example of FIGS. 8A-8C, a bottom layer (BL) 802 is formed over the substrate 302 including deposited in the trenches 704 and over the fins 702. A middle layer (ML) 804 deposited over the bottom layer 802. A photosensitive layer 806 deposited over the middle layer 804 and patterned using photolithography techniques to form openings 808. The openings 808 is overlying a middle portion of a fin 702 and thereby defines a fin cut area.

The photosensitive layer 806 is a photoresist in some embodiments. The bottom layer 802 is a bottom anti-reflective coating (BARC) layer in some embodiments. In an embodiment, the BL 802 is an ashing removal dielectric (ARD) layer. In a further embodiment, the BL 802 is an ARD layer such as amorphous carbon. In some embodiments, the bottom layer 802 has a planarized upper surface. The BL 802 may have an upper surface above the fin elements 702.

The middle layer 804 may be an inorganic material. In a further embodiment, the middle layer 804 is a nitride such as silicon nitride, an oxynitride such as silicon oxynitride, or an oxide such as silicon oxide. In an embodiment, the ML 804 having an inorganic composition is formed on the BL 802 having an organic composition.

In an embodiment, the BL 802 has a thickness of between approximately 2000 Angstroms and approximately 2500 Angstroms. In an embodiment, the ML 804 has a thickness of between approximately 250 Angstroms and 400 Angstroms. In an embodiment, the photoresist layer 806 has a thickness between approximately 750 Angstroms and 950 Angstroms. That is, in some embodiments, the BL 802 is more than two times the thickness of the photoresist layer 806 and 5-9 times the thickness of the ML 804.

Thus, patterning layers (BL, ML, and the photoresist) are deposited on the substrate as discussed above. And the photoresist layer is patterned to form openings where the fin structures are to be cut. In other words, a pattern is developed to cut one or more fin structures into two separate active regions. Some approaches to manufacturing semiconductor devices involve utilizing a single etching operation to etch through various layers, such as the middle layer and the bottom layer, in order to remove a portion of the targeted area. However, this single etching operation fails to adequately account for the unique characteristics of the differences in the etching from a central zone (e.g., Z1) of a wafer and an edge zone (e.g., Z4) of the wafer. For example, differences in the etching from the central to edge zone can result in differing profiles of the sidewall of the cut fin from the central zone to the edge zone. To the extent that a variation in etching is not accounted for, a resulting edge region of the fin may be different in profile between zone Z1 and zone Z4. In particular, the etching depth of the fin at a zone (e.g., edge zone (Z4)) may be less than the etching depth at another zone (e.g., the center zone). Consequently, the resulting structure may fall short of ideal expectations. A notable issue may be the edges of the cut fin may be different between zones to the extent of taper and/or bowing. In other words, the bowing (increasing of thickness of the opening) can occur at a higher point on the fin in one zone (e.g., edge) or in other words, the etching can remove additional regions in the x-direction of alternating epitaxial layers rather than the lower fin portion formed on the substrate (e.g., in edge region). Certain aspects of improving the etching process uniformity are discussed in the steps that follow.

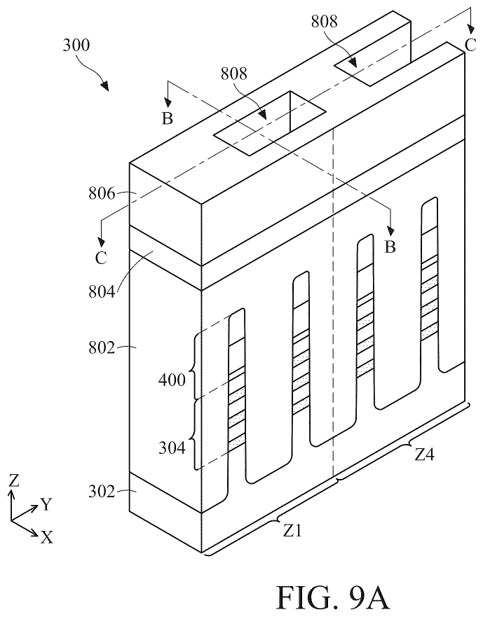

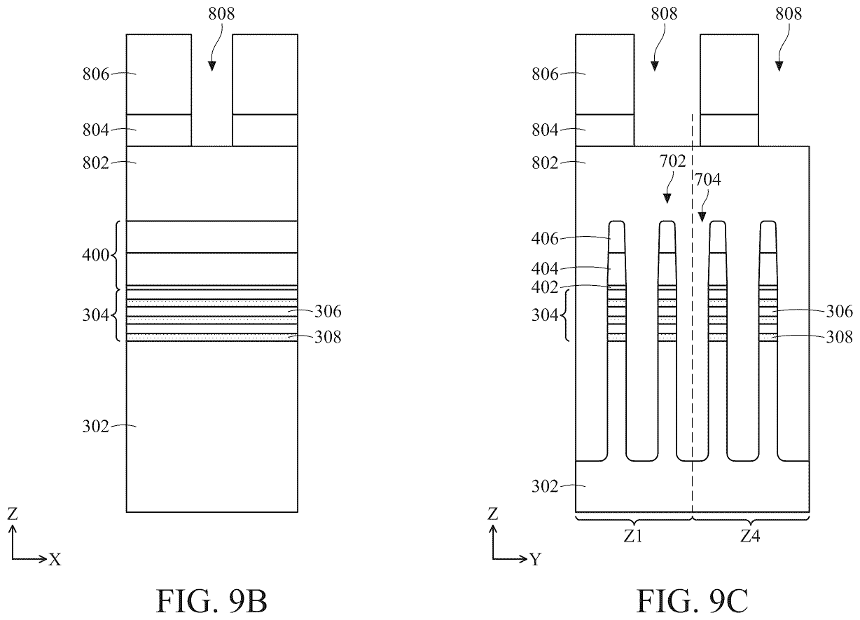

At operation 214, the method 200 performs a first etching step of the fin cut process, which extends the opening 808 through the middle layer 804, as shown in the example of FIGS. 9A-9C. While the precise etchants and parameters utilized are dependent at least in part upon the materials chosen for the middle layer 804, in an embodiment the first etching combination of etchants may comprise a combination of CH₂F₂ and CF₄ and/or other suitable etchants. In an embodiment, a pressure is set to between about 10 mtorr and about 30 mtorr. The first etching combination of etchants may be ignited into plasma. A power of between about 400 W and about 800 W is implemented; an AC voltage between approximately 200 V and about 600 V may be provided. Additionally, the transformer-coupled capacitive tuning (TCCT) parameter may be set to between about 1 and about 3. In an embodiment, the parameters of the first etching process may be selected to extend the opening through the ML 804 without extending into the BL 802. In an embodiment, the ML 804 is etched using a process temperature profile that varies depending on the zones of the wafer such as illustrated with respect to the wafer 100 of FIG. 1. In particular, in an embodiment, a first temperature (T1) may be provided at Z1, a second temperature (T2) at Z2, a third temperature (T3) at Z3, and a fourth temperature (T4) at Z4. In an embodiment, T4 is less than T1, T2, and/or T3. In an embodiment, each of T2 and T3 are less than T1. T1, T2, T3, and/or T4 may be between approximately 50 and 60 Celsius. In an embodiment the process conditions are maintained and the middle layer 804 is exposed for a time period of between about 20 seconds and about 70 seconds. Once the etching process has been performed to a desired length, such as etching through the middle layer 804, the first etching step is stopped. Once the first etching process has been stopped, the conditions within an etching chamber may be modified to provide the block discussed below.

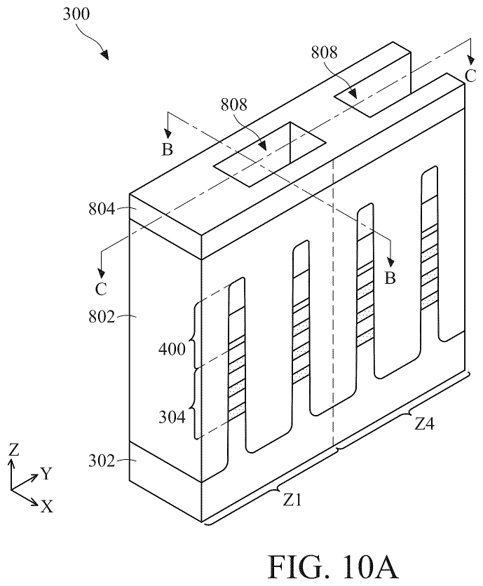

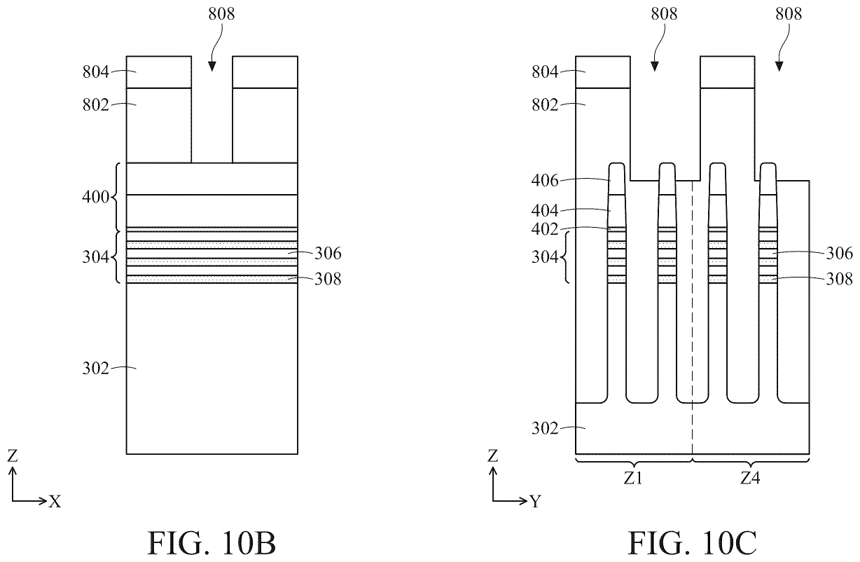

At block 216, the method 200 performs a second etching step of the fin cut process by extending the opening 808 into a top portion of the bottom layer 802, as shown in the example of FIGS. 10A-10C. In an embodiment, the photosensitive layer 806 may be consumed during the second etching step. While the precise etchants utilized are dependent at least in part upon the materials chosen for the bottom layer 802, in an embodiment the second etching combination of etchants may comprise a combination of SO₂, O₂ along with a diluent such as helium (He). In an embodiment, a pressure is lower than the first etching step, such as being set to between about 1 mtorr and about 10 mtorr. A plasma may be provided by a power of between about 300 W and about 700 W. In an embodiment, the power is lower than the first etching step. Additionally, the transformer-coupled capacitive tuning (TCCT) parameter may be set to between about 0.7 and about 2. In an embodiment, this TCCT parameter is decreased from the TCCT parameter applied in the first etching step. In an embodiment the RF generator supplies an AC voltage of between about 200 V and about 600 V. In an embodiment, the voltage is greater than the first etching step. In second etching processes, a high voltage bias pulsing (HVBP) etching process is performed duty cycle of approximately 10-20% (e.g., % high voltage bias applied at the substrate level versus zero bias voltage applied) to improve etching selectivity.

In an embodiment of the second etching step, the process is performed at 100-300 Hz. The BL 802 may be etched using a process temperature profile that varies depending on the zones of the wafer such as illustrated with respect to the wafer 100 of FIG. 1. In particular, in an embodiment, a first temperature (T5) may be provided at Z1, a second temperature (T6) at Z2, a third temperature (T7) at Z3, and a fourth temperature (T8) at Z4. In an embodiment, T8 is greater than T5, T6, and/or T7. In an embodiment, each of T6 and T7 are less than T5. In an embodiment the process conditions are maintained and the bottom layer 802 is exposed for a time period of between about 70 seconds and about 150 seconds.

Once the etching process has been performed to a desired length, such as exposing the oxide layer 406, the second etching conditions may be stopped. In an embodiment, a certain extent of over-etching (e.g., 10% to 30% of the thickness of oxide layer 406) may be provided. In an embodiment, a bottom surface of the BL 802 in the opening 808 may be substantially similar at an edge region Z4 and a center region (e.g., Z1).

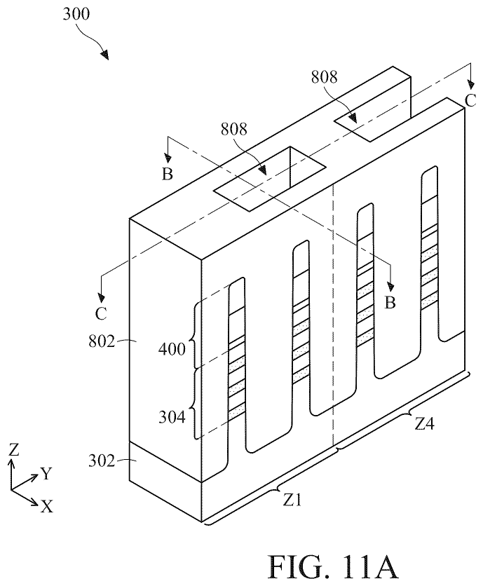

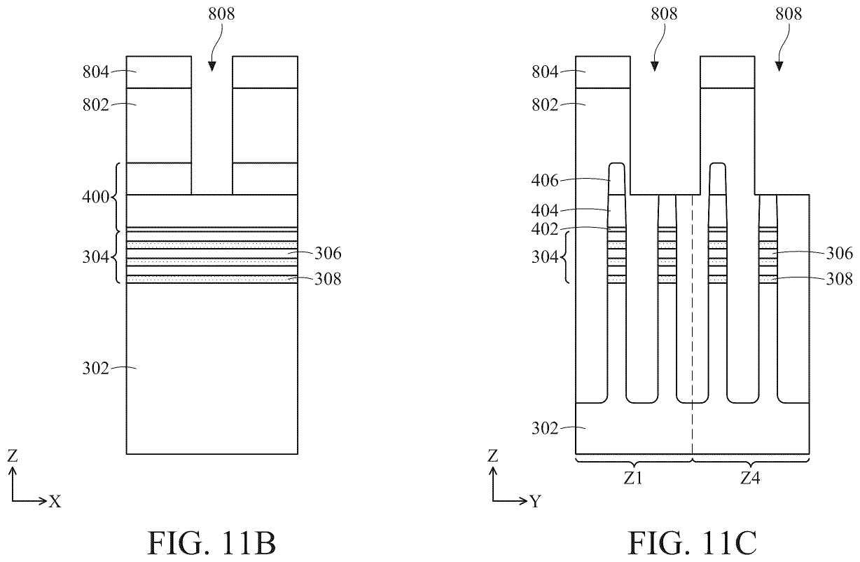

At block 218, the method 200 performs a third etching step of the fin cut process by etching the oxide layer 406 removing it from within the opening 808, as shown in the example of FIGS. 11A-11C. The BL 802 may also be etched during the third etching step. While the precise etchants utilized are dependent at least in part upon the materials chosen for the oxide layer 406, in an embodiment the third etching combination of etchants may comprise a combination of SO₂, CHF₃ along with a diluent such as helium (He), and/or other suitable etchants. In an embodiment, a pressure is between 1 and 10 mtorr. A power of between about 300 W and about 1000 W may be implemented to generate a plasma. Additionally, the transformer-coupled capacitive tuning (TCCT) parameter may be set to between about 0.5 and about 1.2. In an embodiment, the TCCT is less than that of the second etching step. An AC voltage of between about 300 V and about 600 V. In an embodiment, this voltage is increased from the voltages applied in the first and second etching steps. In an embodiment, the third etching process may be performed using a temperature profile that varies depending on the zones of the wafer such as illustrated with respect to the wafer 100 of FIG. 1. In particular, in an embodiment, a first temperature (T9) may be provided at Z1, a second temperature (T10) at Z2, a third temperature (T11) at Z3, and a fourth temperature (T12) at 74. In an embodiment, T12 is greater than T11, T10, and/or T9. In an embodiment, each of T11 is greater than T10 and T10 is greater than T9.

In an embodiment, the process conditions are provided until the oxide layer 406 is removed and the nitride layer 404 is exposed. In an embodiment the process conditions are maintained for a time period of between about 10 seconds and about 25 seconds. Once the etching process has been performed to a desired length, such as exposing the nitride layer 404 of the fin 702, the third etching step is stopped.

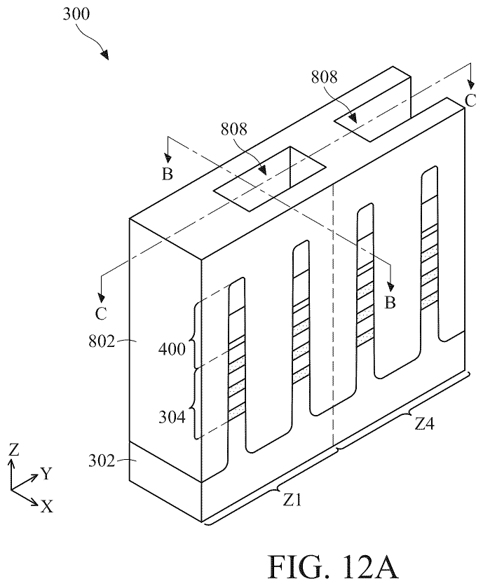

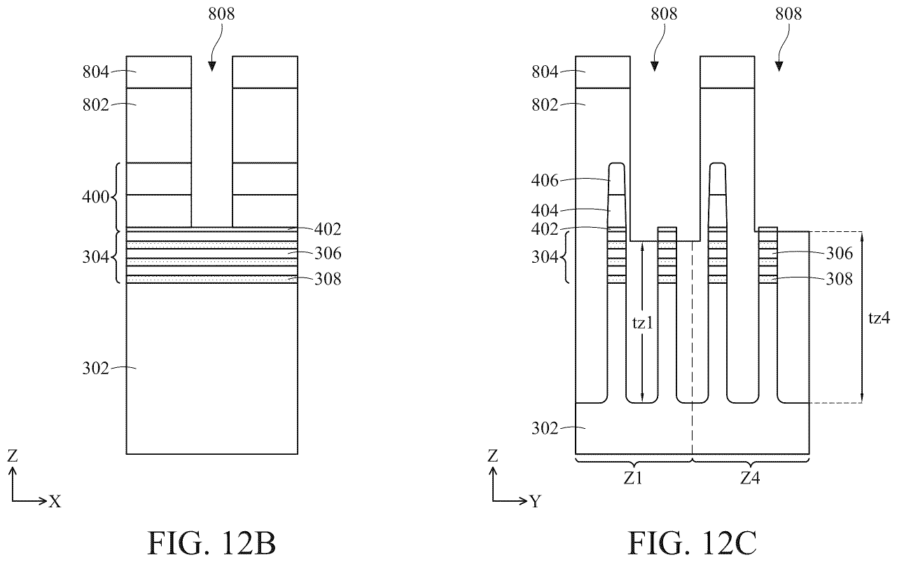

At block 220, the method 200 performs a fourth etching step of the fin cut process by that etches the nitride layer 404 to extends the opening 808 to remove the nitride layer 404 within the opening 808, as shown in FIGS. 12A-12C. The fourth etching step also etches the BL 802 adjacent the fin 702. In some cases, the fourth etching step may be referred to as an SNOE etch providing a silicon nitride etch possibly including an over-etch component.

While the precise etchants utilized may be dependent at least in part upon the materials chosen for the nitride layer 404 in some cases, in an embodiment the fourth etching combination of etchants may comprise a combination of SO₂, CHF₃, oxygen (O₂), argon, and Helium. Other possible etchants include CH₂F₂, NF₃, CF₄ and/or other suitable etchants. In an embodiment, a pressure in the fourth etching step may be between 50 mtorr and 130 mtorr. In an embodiment, the pressure is increased from the third etching step (and greater than the first and second etching steps). In the fourth etching step, a plasma may be generated using a power of between about 500 W and about 1000 W. This power is increased from the power applied in the third etching step. And in further embodiments, power is increased from the first and second etching steps. Additionally, the transformer-coupled capacitive tuning (TCCT) parameter may be set to between about 0.4 and about 1. In an embodiment, the TCCT parameter is 0.5. Thus, TCCT is an edge mode. It is noted that TCCT is provided to an extent that does not affect trench CD negatively, which may occur at lower TCCT parameters with respect to this etching step. In an embodiment, the TCCT parameter is less than the third etching step (and the first and second etching steps). This range for the TCCT parameter safeguards uniformity in extending the opening 808 further into the bottom layer 802. The etching process may also provide an AC voltage to an electrode between about 250 V and about 500 V. In an embodiment, this voltage is reduced from the voltages applied in the second and third etching steps.

In an embodiment, the fourth etching process may be performed using a temperature profile that varies depending on the zones of the wafer such as illustrated with respect to the wafer 100 of FIG. 1. In particular, in an embodiment, a first temperature (T13) may be provided at Z1, a second temperature (T14) at Z2, a third temperature (T15) at Z3, and a fourth temperature (T16) at Z4. In an embodiment, T16 is less than T15, T14, and/or T13. In an embodiment, T16 is approximately 10% lower than T15, T14, and/or T13. In an embodiment, T16 is about 5 degrees Celsius lower than T15, T14, and/or T13. In an embodiment, T15, T14 and T13 are approximately equal to one another. The fourth etching process can be performed at temperatures ranging from 40 degrees Celsius to about 70 degrees Celsius. For example, in an embodiment, T13, T14, T15 are approximately 50 degrees Celsius and T16 is approximately 45 degrees Celsius.

It is noted that in the fourth etching step etching the nitride, an etchant gas may be rich in polymers and thus, sensitive to temperature variations such as provided between the zones. In some implementations, the fourth etching rate provides for an endothermic reaction to drive the etching (e.g., Si3N4+H+CFx♯HCN+SiFx; Si3N4+CHFx♯HCN+SiFx). Thus, increasing the temperature (e.g., zones Z1, Z2, Z3) reduces the etch rate (e.g., in comparison with zone Z4). And decreasing the temperature at the edge zone (Z4) will increase the etch rate to provide additional etching. The increase in etch rate at the zone 4 may be between approximately 10 to 25% relative to zone 1. The increase in etch rate may serve, along with for example the fifth etching step, a tuning of the profile of the edge of the cut fin (e.g., driving the bulb-shape lower at the edge region) to improve uniformity across the wafer as discussed herein.

In an embodiment the process conditions of the fourth etching step are maintained for a time period of between about 10 seconds and about 60 seconds. The decrease in temperature at the edge region (Z4) as shown in T16 provides for a controlled nitride removal. In some embodiments, the decrease in temperature provides for maintaining a substantially linear sidewall. As illustrated, the fourth etching step also etches the BL 802 adjacent the fin 702. In an embodiment, after the fourth etching process the BL 802 is thicker (e.g., has an upper surface further from a surface of the substrate) in the edge region Z4 than in the center region Z1. This is illustrated by FIG. 12C, which illustrates tz4 is greater than tz1. In an embodiment, tz4 is between 10 to 25% greater. In an embodiment, tz4 is substantially equal to tz1.

Once the etching process has been performed to a desired length, such as exposing the pad oxide layer 402 of the fin 702, the fourth etching step may be stopped. Once the etching process has been stopped, the conditions may be modified to provide the fifth etching step below. In the illustrated embodiments as shown in FIG. 12B, at the conclusion of the fourth etching step, the nitride layer 404 is etched through. In an embodiment, the top surface of the oxide layer 402 is exposed. And the top surface of the BL 802 adjacent the fin 702 is below a top surface of the oxide layer 402. As discussed above, the etching rate at the outer edge of the wafer is increased in the fourth etching step in comparison with the etching rate at the center of the wafer in the fourth etching step.

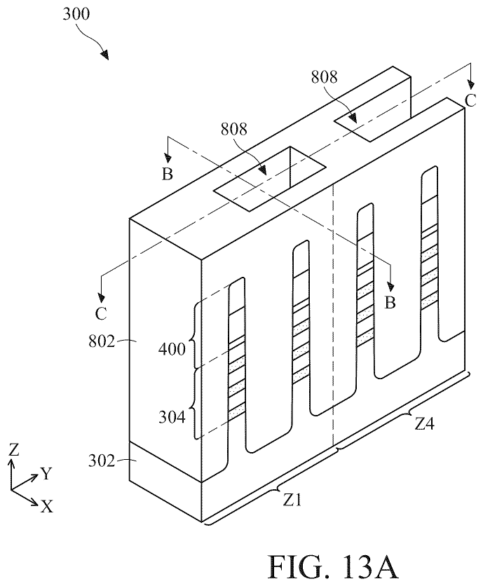

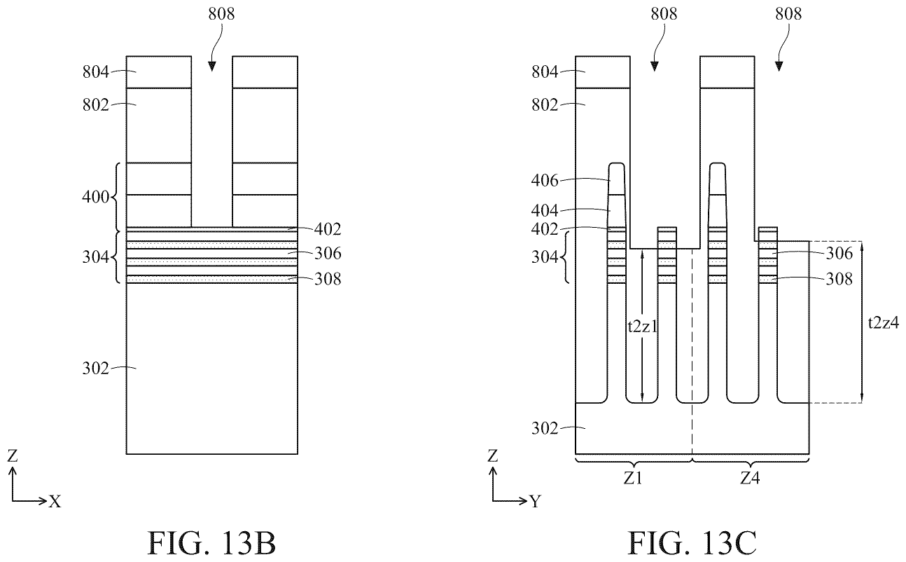

At block 222, the method 200 performs a fifth etching step of the fin cut, which etches the exposed oxide layer 402 and portions of the exposed BL 802 adjacent the fin 702. FIGS. 13A-13C are exemplary and illustrate in an embodiment, a top layer of the epitaxial stack 304 (e.g., layer 308) may be exposed after the fifth etching step.

While the precise etchants utilized are dependent at least in part upon the materials chosen for the oxide layer 402, in an embodiment the fifth etching combination of etchants may comprise a combination of CF₄ and Helium. In an embodiment, a pressure in the fifth etching step may be between 1 mtorr and 10 mtorr. In an embodiment, the pressure is lower than the fourth etching step. In some implementations, the pressure is substantially the same as the second and third etching steps. In the fifth etching step, a plasma may be generated using a power of between about 300 W and about 500 W. This power is decreased from the power applied in the fourth etching step.

Additionally, the transformer-coupled capacitive tuning (TCCT) parameter may be set to between about 0 and less than about 0.5. In an embodiment, the TCCT parameter may be 0.3. In other words, the process may be strongly tuned to edge mode. In an embodiment, the TCCT parameter is less than the fourth etching step (and the first, second, and third etching steps). This range for the TCCT parameter safeguards uniformity in extending the opening 808 further into the oxide layer 402 and the BL 802 by increasing the etching of an edge region Z4. In particular, the TCCT provides for center-edge plasma distribution by increasing the etch rate at the edge zones of the wafer providing an increased plasma concentration on an edge region Z4 relative to the center region Z1. That is, the plasma concentration of the fifth etching step may be tuned by a bias voltage between the center and edge provided by the TCCT setting. The bias voltage at the center may be 140-160 V, and the bias voltage at the edge may be 40-60 V. In an embodiment, the plasma concentration of the fifth etching step may be between about 0.1 to about 3.5 ug/mL. The low value of TCCT drives, at the edge region (Z4), an increased depth of the BL 802. In some embodiments, the increase in depth allows for maintaining a substantially linear sidewall. It is noted that the TCCT parameter may be selected to drive the etch rate uniformity across the wafer due to less polymer gas during the fifth etching step, which makes the TCCT parameter have increased sensitivity (e.g., compared to fourth etching step, which has temperature as a suitable tuning knob).

TCCT parameter is defined by match circuitry that enables dynamic tuning of power provided to the inner and outer coils. The coil includes connections to the inner coil, and outer coil. In one embodiment, the TCCT is configured to tune the TCP coil to provide more power to the outer coil versus the inner coil as provided in the fifth etching step. Thus, there is an uneven distribution of power and/or control the ion density in a radial distribution over the substrate (i.e., wafer, when present).

The etching process may also provide an AC voltage to an electrode between about 100 V and about 350 V. In an embodiment, this voltage is reduced from the voltages applied in the fourth etching steps. In fifth etching processes, a high voltage bias pulsing (HVBP) etching process is performed duty cycle of approximately 40-60% (e.g., 50% high voltage bias applied at the substrate level versus zero bias voltage applied, to improve etching selectivity.

In an embodiment, the fifth etching process may be performed using a temperature profile that varies depending on the zones of the wafer such as illustrated with respect to the wafer 100 of FIG. 1. In particular, in an embodiment, a first temperature (T17) may be provided at Z1, a second temperature (T18) at Z2, a third temperature (T19) at Z3, and a fourth temperature (T20) at Z4. In an embodiment, T20 is greater than T19, T18, and/or T17. In an embodiment, T20 is approximately 10% greater than T19. In an embodiment, T19 is greater than T18, and T18 is greater than T17 (e.g., by a difference of about 10%). In some implementation, the temperatures are T17 of 45° C., T18 of 48° C., T19 of 50° C., and T20 (edge) of 55° C. In an embodiment the process conditions of the fifth etching step are maintained and the oxide layer 402 and BL 802 is exposed for a time period of between about 5 seconds and about 25 seconds.

Once the etching process has been performed to a desired length, such as exposing the epitaxial stack 304 of the fin 702, the fifth etching step may be stopped. Once the etching process has been stopped, the conditions may be modified to provide the sixth etching step below. In the illustrated embodiments as shown in FIG. 13B, at the conclusion of the fifth etching step, the oxide layer 402 is etched through. In an embodiment, the top surface of the epitaxial stack 304 is exposed. As discussed above, the TCCT parameter allows for increasing the depth including at an outer region of the wafer 100. It is noted that the TCCT parameter is tuned to provide the increased etching. In an embodiment, the thickness of BL 802 in the edge region Z4 is greater than the center region Z1 as shown in FIG. 13C with respect to t2z1, t2z4. In an embodiment, t2z4 is between 10 to 25% greater than t2z4. In an embodiment, t2z4 is substantially equal to t2z1.

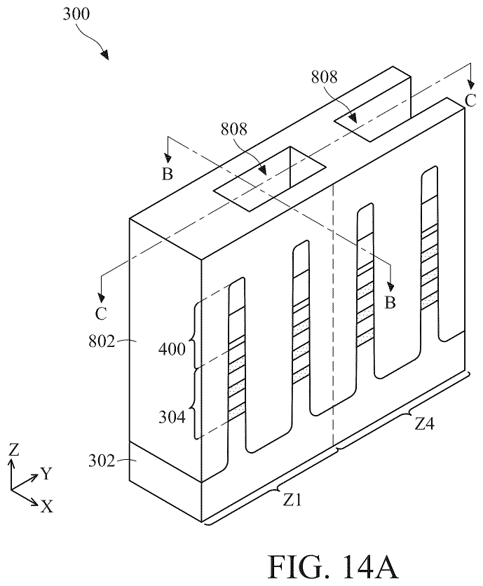

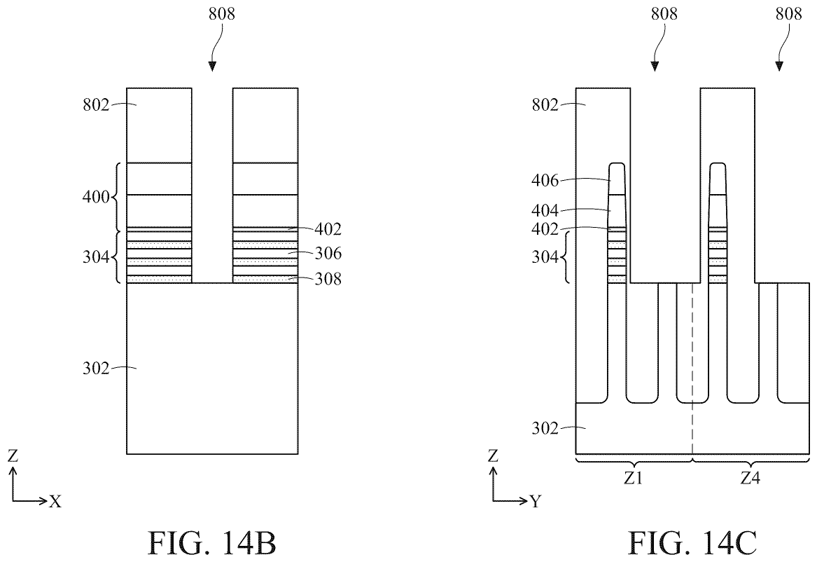

At block 224 of the method 200, a sixth etching step is performed. The sixth etching step etches the epitaxial stack 304 and extends the opening 808 through the epitaxial stack 304, as shown in FIGS. 14A-14C. While the precise etchants utilized are dependent at least in part upon the materials chosen for the epitaxial stack 304, in an embodiment the sixth etching combination of etchants may comprise CH2F2, SF6, CH3F, and Helium. In an embodiment, a pressure in the is between about 1 mtorr and about 10 mtorr. In some implementations, a high voltage bias pulsing (HVBP) etching process is performed duty cycle of approximately 10-30% (e.g., % high voltage bias applied at the substrate level versus zero bias voltage applied, to improve etching selectivity.

In an embodiment, the sixth etching process provides a plasma using a power of between about 360 W and about 400 W. In an embodiment, this power is slightly higher from the power applied in the fifth etching step. Additionally, the transformer-coupled capacitive tuning (TCCT) parameter may be set to between about 2 and about 4. In an embodiment, the TCCT parameter in the sixth etching step is increased from the TCCT parameter in the fifth etching step. An AC voltage of between about 400 V and about 500 V. In an embodiment, this voltage is the highest of the etching steps performed to this point. In an embodiment, the temperature of the process is uniform across the wafer. For example, the temperature may be between approximately 40 and 50 Celsius.

Once the etching process has been performed to a desired length, such as exposing the fin base of the fin 702, the sixth etching step may be stopped. In an embodiment, the sixth etching step may be between approximately 5 and 13 seconds.

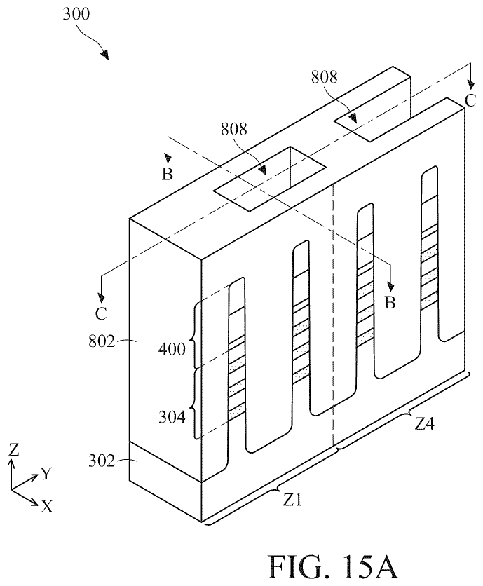

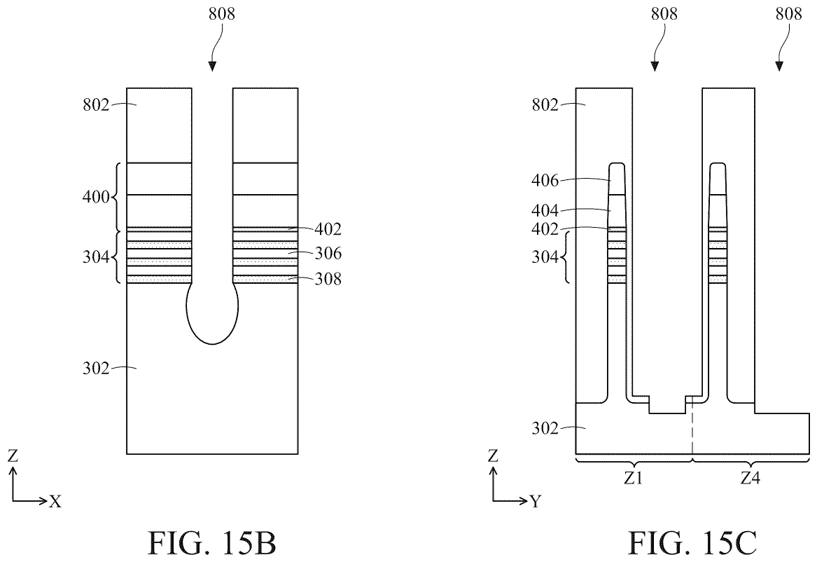

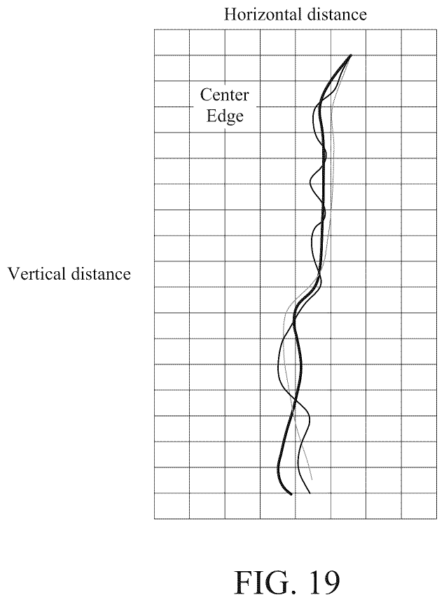

At operation 126, the method 200 performs a seventh etching step of the fin cut process, which etches the fin base and extends the opening 808 further downward, as shown in FIGS. 15A-15C. It is noted that the bulb shape is illustrated in the cross-sectional view of FIG. 15B, which illustrates curvilinear sidewalls to a bottom region of the opening 808. In some implementations of the method 200, the bulb shape is below the stack 304 at both the center region Z1 and the edge region Z4. In some implementations, the fin edge in the center region and the edge region is substantially similar in terms of its profile. That is, the fin edge in the center region has a degree of taper or linearity including extent of curvilinearity that is substantially the same such as within 1 nanometer horizontal offset at a given portion (e.g., a layer 206 or fin base). In a further embodiment, the degree of offset is within approximately 0.5 nm. In yet a further embodiment, the degree is within approximately 0.2 nm measured at a layer 208 second from a top of the fin 702. This is further discussed with reference to FIG. 19.

While the precise etchants utilized for the seventh etch are dependent at least in part upon the materials chosen for the substrate 302, in an embodiment seventh etching combination of etchants may comprise CH₂F₂, SF₆, CH₃F, and Helium. In an embodiment, a pressure is between about 1 mtorr and about 10 mtorr. In an embodiment the seventh etching process provides a plasma using a power of between about 360 W and about 400 W. In an embodiment, the power and pressure are substantially the same as the sixth etching step. Additionally, the transformer-coupled capacitive tuning (TCCT) parameter may be set to between about 2 and about 4. In an embodiment, the TCCT parameter in the seventh etching step is substantially the same as the TCCT parameter in the sixth etching step. An AC voltage of between about 450 V and about 550 V. In an embodiment, this voltage is the higher than the voltage of the sixth etching step. In an embodiment, it may be the highest voltage of the etching steps previously described. In an embodiment, the temperature of the process is uniform across the wafer. For example, the temperature may be between approximately 40 and 50 Celsius. In an embodiment, the seventh etching step may be between 15 and 25 seconds.

Once the etching process has been performed to a desired length, such as recessing the fin base to a certain depth, the seventh etching step may be stopped. Again, as illustrated in FIG. 15B, at the conclusion of the seventh etching step, the lower portion of the opening 808 as under the epitaxial stack 304 has a bulb shape. In other words, the edge or sidewall is curvilinear in profile. The curve of the curvilinear profile curves into the fin base as the sidewall extends further below the epitaxial stack before curving back towards the opening near the bottom of the opening 808. The bulb-shape having increasing width does not begin until below a bottom plane of the epitaxial stack 304. In some embodiments of the method, this configuration is provided at a center region of the wafer (e.g., Z1) as well as the edge region of the wafer (e.g., Z4). As the etching parameters of the fourth and fifth etches are tailored to ensure the etching at the edge region is sufficient in depth (e.g., bottom layer BL 802 etching depth), there is a reduced risk of the increase in width being adjacent the epitaxial stack 304 at the edge region (Z4).

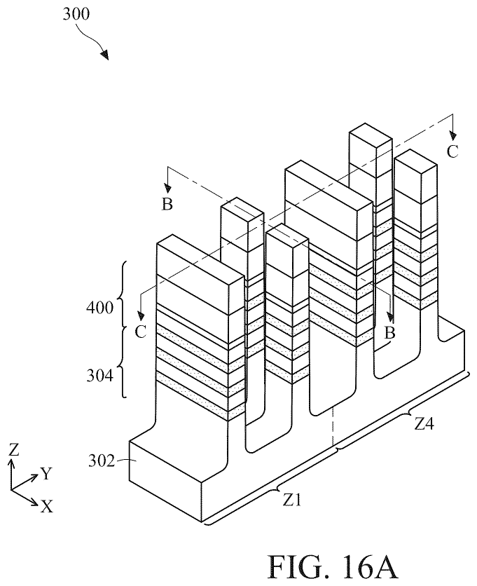

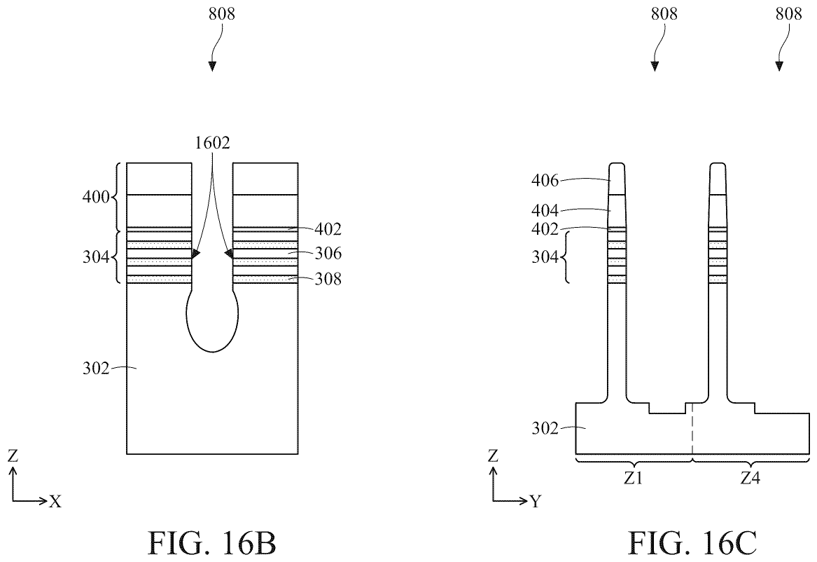

After the etching steps, the fin cut process may further perform a cleaning process or a wet-etching process to remove the remaining portion of the bottom layer 802. The resultant structure is shown in FIGS. 16A-16C. The fin cut process “cuts” one of the fins (active regions) into two segments with opposing fin edges 1602. In particular, at block 128, the method 200 removes the bottom layer 802. In some embodiments, the etching operations are performed using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In other embodiments, the etching operation is performed using a wet etchant such as, but not limited to, HF:HNO₃ solution, HF:CH₃COOH:HNO₃, or H₂SO₄ solution and HF:H₂O₂:CH₃COOH.

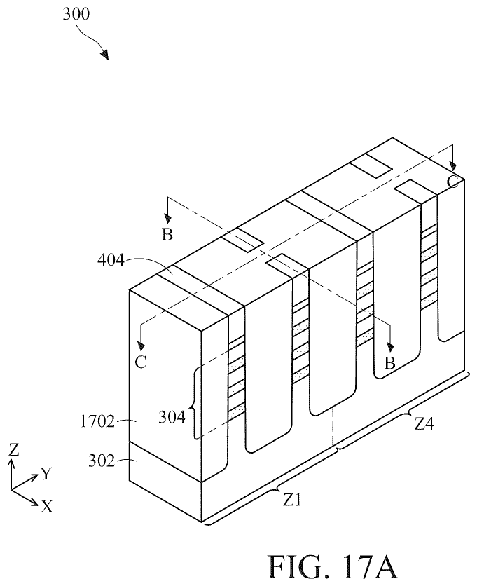

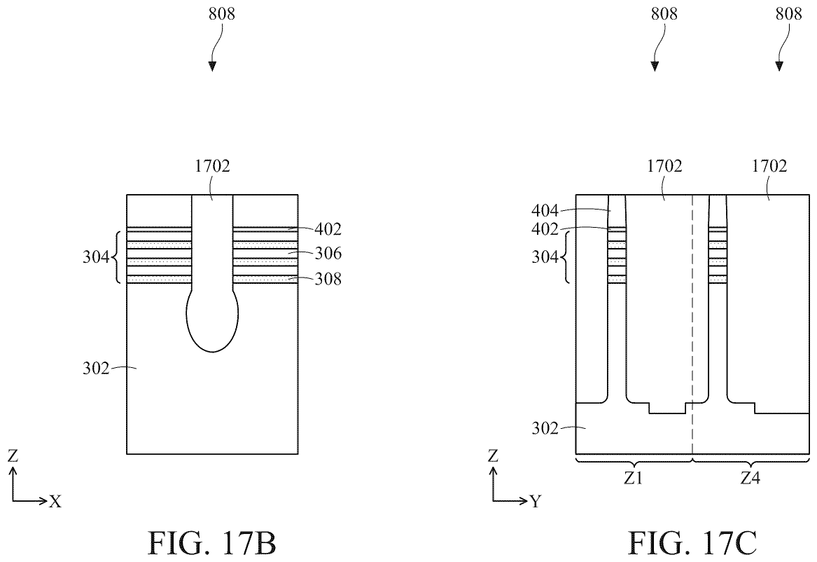

At block 230, the method 200 deposits a dielectric material in the trenches 704 between adjacent fins 702 and in between the now-cut portions of fin 702 to form an isolation feature 1702, as shown in FIGS. 17A-17C. The isolation feature 1702 may include one or more dielectric layers. Suitable dielectric materials for the isolation feature 1702 may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. Then, a planarization operation, such as a CMP process, is performed such that the upper surface of the nitride layer 404 is exposed from the isolation feature 1702. In some embodiments, the CMP process further removes the nitride layer 404, oxide layer 402, and exposes the upper surface of the topmost epitaxial stack 304 layer.

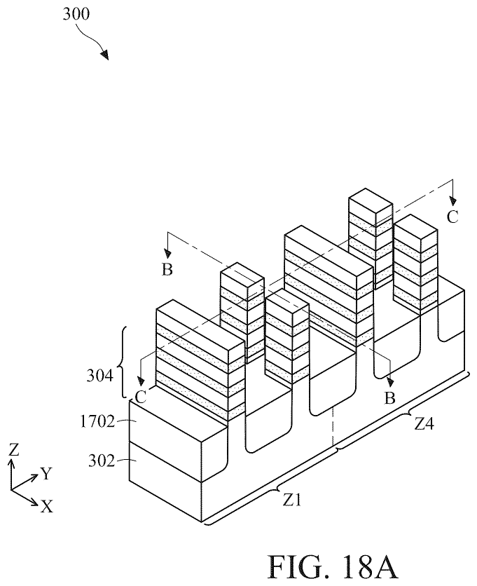

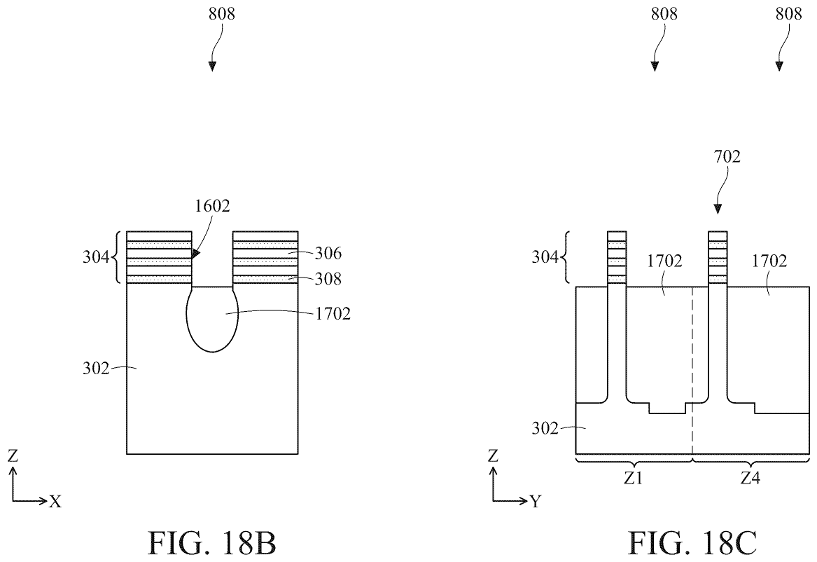

At block 232, the method 200 recesses the isolation feature 1702 to form shallow trench isolation (STI) features, as shown in FIGS. 18A-18C. Any suitable etching technique may be used to recess the isolation features 1702 including dry etching, wet etching, RIE, and/or other etching methods, and in an exemplary embodiment, an anisotropic dry etching is used to selectively remove the dielectric material of the isolation features 1702 without etching the fins 702. In some embodiments, any remaining hard mask layer is removed by a CMP process performed prior to the recessing of the isolation features 1702. In an embodiment, the top surface of the STI features 1702 may be below the bottom surface of the epitaxial stack 304. Alternatively, the top surface of the STI features 1702 may be coplanar with the bottom surface of the epitaxial stack 304.

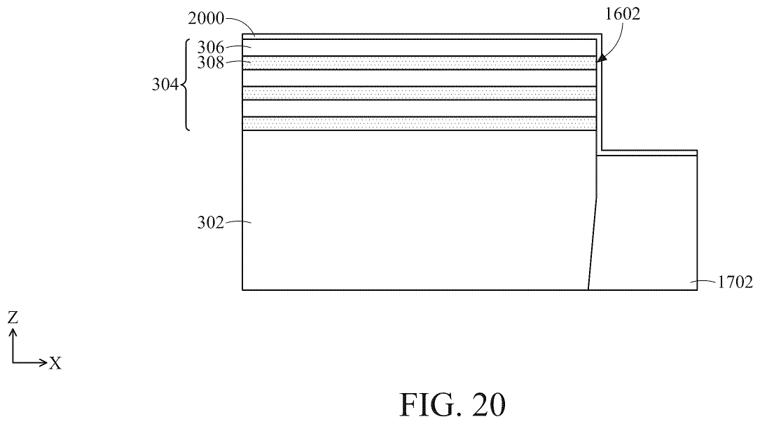

As illustrated in FIG. 18B, the fin edge 1602 formed by the fin cut process and the STI feature 1702 deposited on the fin edge 1602. A gate structure may be subsequently formed on the fin edge as illustrated in FIGS. 20-22 that follow. However, prior to turning to the formation of the dummy gate structures, FIG. 19 is provided to illustrate the fin edge 1602 as provided at a center region of the wafer 100 (e.g., Z1) and the edge region of the wafer 100 (e.g., Z4). As illustrated in the graphical representation of FIG. 19, there edge and center devices have substantially similar fin edge profiles.

As indicated above, in some embodiments, the active regions prepared through the method 200 and block 230 may be further processed to form dummy gate structures, grow source/drain regions, release the channel layers, and form a functional gate structure or structures. Certain aspects of these features are provided below.

At block 234, the method 200 conformally deposits an oxide layer 2000 on the top and sidewall surfaces of the epitaxial stack 304 and the top surface of the STI feature 1702, as shown in FIG. 20. In some embodiments, the oxide layer 2000 is thermal oxide formed by a thermal oxidation process conducted in oxygen ambient. In some embodiments, the oxide layer is formed by CVD, PVD, ALD, or other suitable techniques. The oxide layer may also be referred to as dummy gate dielectric. The oxide layer 2000 is a conformal deposition including in the center zones Z1 and edge zones Z4.

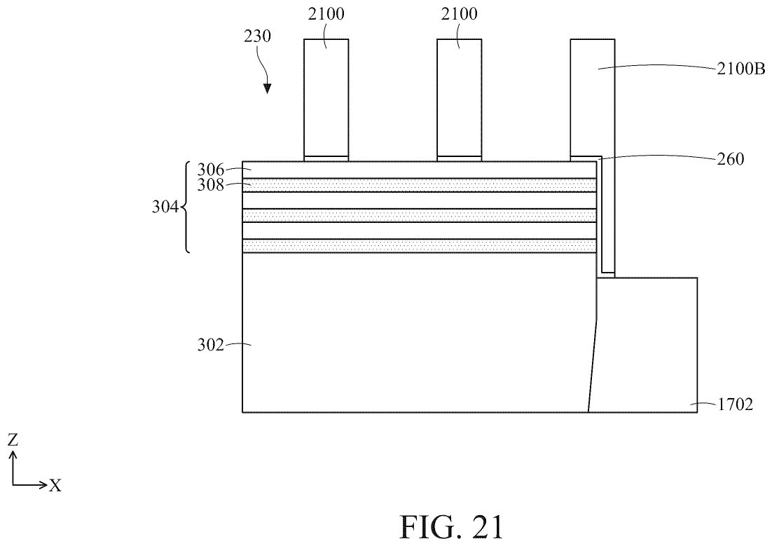

At block 236 of the method 200, sacrificial (dummy) gate structures 2100, as shown in FIG. 21 are formed. In the illustrated embodiment, two (2) sacrificial gate structures 262 are formed on the top surface of the fin 702 and one (1) sacrificial gate structure is formed on the edge of the fin 702, but the number of the sacrificial gate structures 2100 is not so limited. The two sacrificial gate structures 2100 are formed over portions of the fin 702 which are to be channel regions of the to-be-formed GAA transistors. The one sacrificial gate structure 2100B deposited on the edge of the fin 702 covers the edge or sidewalls 1602 and lands on the top surface of the STI feature 1702. The sacrificial gate structures 2100 may include polycrystalline silicon or amorphous silicon. A layer of polycrystalline silicon or amorphous silicon may be deposited using CVD, PVD, ALD, or other suitable process, and patterned into the sacrificial gate structures 2100. The patterning process also removes portions of the oxide layer 2000 not covered by the sacrificial gate structures 2100. By patterning the sacrificial gate structures 2100, the fin 702 are partially exposed on opposite sides of the sacrificial gate structures 2100, thereby defining source/drain (S/D) regions.

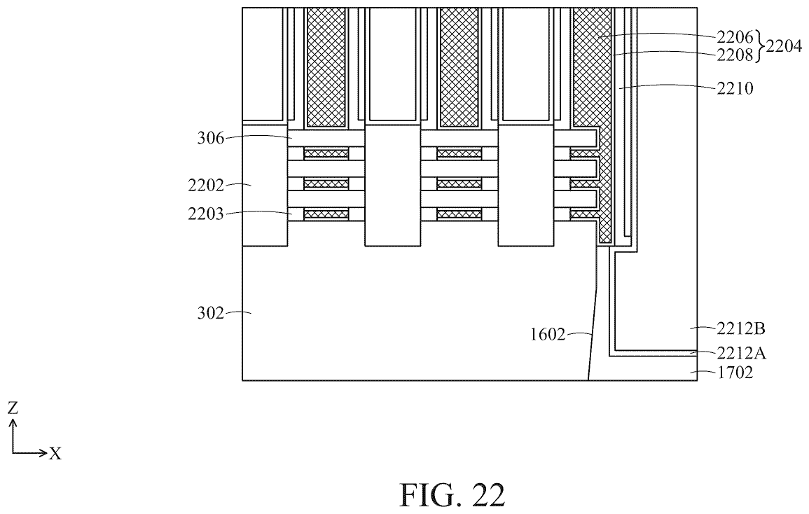

At block 238, the method 200 then continues to include other fabrication processes some of which that are provided while the dummy gate structure 2100B covers the fin-cut region. The processes include, but are not limited to, forming gate spacers 2210 on the sidewalls of the structures 2100, recessing portions of the fin 702 to form S/D trenches (or S/D recesses) and epitaxially growing source/drain region(s) 2202 within the trenches. In some implementations, inner spacers 2203 may be formed prior to growing the S/D regions adjacent the stack 304. Dielectric materials 2212 such as a contact etch stop layer (CESL) 2212A may be formed over the S/D epitaxial features and an interlayer dielectric (ILD) layer 2212B over the CESL layer. Subsequently, the sacrificial gate structures 2100 and the underneath oxide layer 2000 are removed, and channel layers (e.g., 306) are released by removal of the sacrificial epitaxial layers 308 from channel regions. Functional gate structures 2204 such as metal gate stacks 2206 with a high-k gate dielectric 2208 are then formed. Interconnect layers such as provided in back-end-of the line (BEOL) structures are then provided to interconnect the functional layers. It is noted that the dummy gate structure 2100B may also be replaced with a metal gate structure as shown in FIG. 22. And in some implementations, the gate 2204 replacing structure 2100B is non-functional. As discussed above, it is noted that the device of FIG. 22 may be disposed in zone Z1 or zone Z4 of the wafer and provide substantially the same configuration.

Thus, provided is a method and resulting structure that provides for etching processes that allow for tuning etch processes across the wafer to provide for substantially similar fin edge profiles in an edge region as a center region in the fin cut process. In an embodiment, the fourth and fifth etching processes of the method 200 are tuned to provide the etching balance across wafer. In an embodiment, the fourth etching process, i.e., targeting nitride etch, provides for a temperature at the edge of the wafer processing (Z4) that increases the etching amount. In an embodiment, the increased etch rate is provided by a decreased temperature when processing the edge (Z4) zone. In a further embodiment, the temperature may be decreased by 10% and/or about 5 degrees. In an embodiment, the fifth etching process has an increased plasma concentration (i.e., an TCCT decrease) that provides for center to edge etching balance. The TCCT controls the transformer coupled plasma (TCP) coil in a plasma processing chamber. In some implementations, when measured at the second sacrificial epitaxial layer of the stack (e.g., second layer 308 from the top of the fin 702), the center/edge bias may improve to be less than 0.5 nanometers (e.g., 2 nanometer center to edge bias).

Although not intended to be limiting, embodiments of the present disclosure provide one or more of the following advantages. For example, embodiments of the present disclosure perform a fin cut process including multiple etching steps, which warrants a substantially vertical or inwardly tilted fin edge. Such fin edge profile advantageously safeguards the fin edge against being exposed due to isolation features' etch loss. Embodiments of the present disclosure can be readily integrated into existing semiconductor manufacturing processes.

In one exemplary aspect, a method is provided that includes providing a substrate having a first region at a center zone and a second region at an edge zone and forming a first fin protruding from the substrate at the first region and a second fin protruding from the substrate at the second region. The first fin and the second fin each include an epitaxial stack over a fin base and a hard mask layer over the epitaxial stack and the epitaxial stack has alternating first and second semiconductor layers of different material compositions and the hard mask layer includes an oxide layer and a nitride layer over the oxide layer. The method includes performing a first etching process to remove the nitride layer from the first fin in the first region using a first process temperature and to remove the nitride layer from the second fin in the second region using a second process temperature. The second process temperature is lower than the first process temperature. A second etching process is performed to remove the oxide layer from the first fin in the first region proving an increased plasma concentration at the second region than the first region during the second etching process. Additional etching is performed to remove a portion of the first fin and a portion of the second fin.

In a further embodiment, the first etching process etches the nitride layer and stops at an upper surface of the oxide layer. And in an embodiment, the second etching process includes etching the oxide layer and exposing an upper surface of the epitaxial stack. The method may include depositing a patterning material over the first fin and the second fin. And the patterning material includes a bottom layer over and adjacent the first fin and the second fin. In a further embodiment, the first etching process and the second etching process etch the bottom layer adjacent the first fin and the second fin. In some implementations, increased plasma concentration is provided by providing a transformer-coupled capacitive tuning (TCCT) parameter less than one. And in an embodiment, the increased plasma concentration is provided by providing a bias voltage at the first region less than a bias voltage at the second region.

In an embodiment, the method also includes performing additional etching to remove the portion of the first fin and the portion of the second fin forms a first recess in the first fin and a second recess in the second fin. In a further embodiment, the method includes depositing dielectric material in the first recess and the second recess. The first recess and the second recess may include a bulb-shape within the fin base.

In another exemplary aspect, a method includes providing a substrate having a center zone and an edge zone. A first fin is formed protruding from the substrate in the center zone and a second fin is formed protruding from the substrate in the edge zone. The first fin and second fin each include a dielectric portion over a semiconductor portion. A bottom patterning layer is formed adjacent the first fin and the second fin and over the dielectric portion of the first fin and the second fin. And plasma etching process is performed to etch the bottom patterning layer adjacent the first fin and the dielectric portion of the first fin with a first set of process parameters while concurrently etching the bottom resist layer adjacent the second fin and the dielectric portion of the second fin with a second set of process parameters different than the first set of process parameters.

In an embodiment, performing the plasma etching process includes performing a first step to remove a nitride layer of the dielectric portion of the first fin and a nitride layer of the dielectric portion of the second fin; and performing a second step to remove an oxide layer of the dielectric portion of the first fin and an oxide layer of the dielectric portion of the second fin. In a further embodiment, after performing the second step a top surface of the semiconductor portion of the first fin and a top surface of the semiconductor portion of the second fin are exposed. In some implementations, the first step of the method includes a first temperature in the first set of process parameters and a second temperature in the second set of process parameters. The first temperature may be greater than the second temperature.

In an embodiment of the method, the second step includes a transformer-coupled capacitive tuning (TCCT) of 0.3. In some implementations, the first set of process parameters includes a first temperature, and the second set of process parameters includes a second temperature. The second temperature may be lower than the first temperature. In an embodiment, the performing the plasma etching is performed at a transformer-coupled capacitive tuning (TCCT) providing a first bias voltage at the center zone and a second bias voltage at the edge zone.

In another exemplary aspect, a semiconductor device is disclosed that includes a first fin base protruding from a center region of a substrate and a second fin base protruding from an edge region of the substrate. And the device includes a first plurality of nanostructures above the first fin base and a second plurality of nanostructures above the second fin base. A first isolation feature is disposed on an edge of the first fin base and a second isolation feature disposed on an edge of the second fin base. The edge of the first fin base is substantially similar in profile of the edge of the second fin base.

In an embodiment, the edge region of the substrate includes approximately 10% of the substrate adjacent an edge of the substrate. And in some implementations, a profile of the edge of the first fin base is curvilinear and a profile of the edge of the second fin base is curvilinear.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a substrate having a first region at a center zone and a second region at an edge zone;
forming a first fin protruding from the substrate at the first region and a second fin protruding from the substrate at the second region, the first fin and the second fin each including an epitaxial stack over a fin base and a hard mask layer over the epitaxial stack, the epitaxial stack including alternating first and second semiconductor layers of different material compositions and wherein the hard mask layer includes an oxide layer and a nitride layer over the oxide layer;
performing a first etching process to remove the nitride layer from the first fin in the first region using a first process temperature and to remove the nitride layer from the second fin in the second region using a second process temperature, wherein the second process temperature is lower than the first process temperature;
performing a second etching process to remove the oxide layer from the first fin in the first region proving an increased plasma concentration at the second region than the first region during the second etching process; and
performing additional etching to remove a portion of the first fin and a portion of the second fin.

2. The method of claim 1, wherein the first etching process etches the nitride layer and stops at an upper surface of the oxide layer.

3. The method of claim 1, wherein there the second etching process etching the oxide layer and exposing an upper surface of the epitaxial stack.

4. The method of claim 1, further comprising:
depositing a patterning material over the first fin and the second fin, wherein the patterning material includes a bottom layer over and adjacent the first fin and the second fin.

5. The method of claim 4, wherein the first etching process and the second etching process etch the bottom layer adjacent the first fin and the second fin.

6. The method of claim 1, wherein the increased plasma concentration is provided by providing a transformer-coupled capacitive tuning (TCCT) parameter less than one.

7. The method of claim 1, wherein the increased plasma concentration is provided by providing a bias voltage at the first region less than a bias voltage at the second region.

8. The method of claim 1, wherein the performing additional etching to remove the portion of the first fin and the portion of the second fin forms a first recess in the first fin and a second recess in the second fin.

9. The method of claim 8, further comprising: depositing dielectric material in the first recess and the second recess.

10. The method of claim 9, wherein each of the first recess and the second recess include a bulb-shape within the fin base.

11. A method, comprising:
providing a substrate having a center zone and an edge zone;
forming a first fin protruding from the substrate in the center zone and a second fin protruding from the substrate in the edge zone, the first fin and second fin each including a dielectric portion over a semiconductor portion;
forming a bottom patterning layer adjacent the first fin and the second fin and over the dielectric portion of the first fin and the second fin; and
performing a plasma etching process to etch the bottom patterning layer adjacent the first fin and the dielectric portion of the first fin with a first set of process parameters while concurrently etching the bottom resist layer adjacent the second fin and the dielectric portion of the second fin with a second set of process parameters different than the first set of process parameters.

12. The method of claim 11, wherein the performing the plasma etching process includes:
performing a first step to remove a nitride layer of the dielectric portion of the first fin and a nitride layer of the dielectric portion of the second fin; and
performing a second step to remove an oxide layer of the dielectric portion of the first fin and an oxide layer of the dielectric portion of the second fin.

13. The method of claim 12, wherein after performing the second step a top surface of the semiconductor portion of the first fin and a top surface of the semiconductor portion of the second fin are exposed.

14. The method of claim 12, wherein the first step includes a first temperature in the first set of process parameters and a second temperature in the second set of process parameters, wherein the first temperature is greater than the second temperature.

15. The method of claim 14, wherein the second step includes a transformer-coupled capacitive tuning (TCCT) of 0.3.

16. The method of claim 11, wherein the first set of process parameters includes a first temperature and the second set of process parameters includes a second temperature, the second temperature lower than the first temperature.

17. The method of claim 11, wherein the performing the plasma etching is performed at a transformer-coupled capacitive tuning (TCCT) providing a first bias voltage at the center zone and a second bias voltage at the edge zone.

18. A semiconductor device, comprising:
a first fin base protruding from a center region of a substrate and a second fin base protruding from an edge region of the substrate;
a first plurality of nanostructures above the first fin base;
a second plurality of nanostructures above the second fin base; and
a first isolation feature disposed on an edge of the first fin base and a second isolation feature disposed on an edge of the second fin base,
wherein the edge of the first fin base is substantially similar in profile of the edge of the second fin base.

19. The semiconductor device of claim 18, wherein the edge region of the substrate includes approximately 10% of the substrate adjacent an edge of the substrate.

20. The semiconductor device of claim 18, wherein a profile of the edge of the first fin base is curvilinear and a profile of the edge of the second fin base is curvilinear.
